(19) United States
(12) Patent Application Publication
(10) Pub. No.: US 2021/0327780 A1
(43) Pub. Date: Oct. 21, 2021

(54) ELECTRONIC DEVICE MODULE HAVING HEAT RADIATING PORTION AND MANUFACTURING METHOD THEREOF

(71) Applicant: Samsung Electro-Mechanics Co., Ltd., Suwon-si (KR)

(72) Inventor: Jung Mok JANG, Suwon-si (KR)

(73) Assignee: Samsung Electro-Mechanics Co., Ltd., Suwon-si (KR)

(21) Appl. No.: 16/997,554

(22) Filed: Aug. 19, 2020

(30) Foreign Application Priority Data
Apr. 21, 2020 (KR) 10-2020-0048274

(51) Int. Cl. H01L 23/367; H01L 23/498

(52) U.S. Cl. CPC H01L 23/367; H01L 23/49816

(57) ABSTRACT

An electronic device module includes: a substrate; a heating element mounted on a first surface of the substrate; a heat radiating portion coupled to one surface of the heating element; a signal transmission portion mounted on the first surface of the substrate and configured to electrically connect the substrate externally; and a sealing portion sealing the heating element, the heat radiating portion, and the signal transmission portion. The heat radiating portion includes: a heat transfer portion having an area larger than an area of the heating element; and a heat release portion protruding from one surface of the heat transfer portion. The heat release portion has an area smaller than the area of the heat transfer portion and has an exposed surface coplanar with an external surface of the sealing portion.

### CROSS-REFERENCE TO RELATED APPLICATIONS

This application claims the benefit under 35 U.S.C. § 119(a) of Korean Patent Application No. 10-2020-0048274 filed on Apr. 21, 2020 in the Korean Intellectual Property Office, the entire disclosure of which is incorporated herein by reference for all purposes.

### BACKGROUND

### 1. Field

The following description relates to an electronic device module having a heat radiating portion, and a manufacturing method of an electronic device module.

### 2. Description of Related Art

Recently, in semiconductor devices, as chip sizes decrease and a number of input/output terminals increases, due to process technologies being miniaturized and functions being diversified, an electrode pad pitch has been gradually refined, and as fusion of various functions is accelerated, a packaging technology for integrating various devices into one package is needed.

In addition to demands for technological improvement, a stacked electronic device module in which a plurality of electronic devices are stacked, or a system-in-package (SIP)-type electronic device module in which electronic devices having different functions are integrated are being manufactured, to control an increase in product price.

As the performance of electronic devices disposed in such an electronic device module increases, a large amount of heat may be generated by the electronic devices. When it is impossible to effectively radiate the heat generated by the electronic devices, there may be a problem that a portion of the electronic device module in which peripheral elements or electronic devices are sealed may be damaged.

### SUMMARY

This Summary is provided to introduce a selection of concepts in simplified form that are further described below in the Detailed Description. This Summary is not intended to identify key features or essential features of the claimed subject matter, nor is it intended to be used as an aid in determining the scope of the claimed subject matter.

In one general aspect, an electronic device module includes: a substrate; a heating element mounted on a first surface of the substrate; a heat radiating portion coupled to one surface of the heating element; a signal transmission portion mounted on the first surface of the substrate and configured to electrically connect the substrate externally; and a sealing portion sealing the heating element, the heat radiating portion, and the signal transmission portion. The heat radiating portion includes: a heat transfer portion having an area larger than an area of the heating element; and a heat release portion protruding from one surface of the heat transfer portion. The heat release portion has an area smaller than the area of the heat transfer portion and has an exposed surface coplanar with an external surface of the sealing portion.

The heat transfer portion may be formed in a flat plate shape or a block shape, and may be formed of a metal material.

The electronic device module may further include connection terminals configured to electrically connect the signal transmission portion externally. The connection terminals may each include a first connection terminal disposed in the sealing portion and bonded to the signal transmission portion, and a second connection terminal disposed externally of the sealing portion and bonded to the first connection terminal.

A bonding surface of the first connection terminal and the second connection terminal may be coplanar with the exposed surface of the heat release portion.

The exposed surface of the heat release portion may include a plurality of exposed surfaces disposed to be spaced apart.

A coupling layer having an increased surface roughness in comparison to the heat radiating portion may be formed on a surface of the heat radiating portion.

A step may be formed on a side surface of the heat radiating portion.

A side surface of the heat radiation portion may be formed as a curved surface.

The heat radiating portion may further include a protrusion protruding from another surface of the heat transfer portion and bonded to the heating element. The protrusion may have an area smaller than the area of the heat transfer portion.

A bonding surface of the protrusion that is bonded to the heating element may have an area smaller than an area of the one surface of the heating element.

The electronic device module may further include: a bonding layer interposed between the heating element and the protrusion. At least a portion of the bonding layer may be disposed in a stepped space formed by a difference in area between the protrusion and the one surface of the heating element.

The electronic device module may further include an element mounted on the first surface of the substrate. At least a portion of the element may be disposed to face a lower surface of the heat transfer portion.

The electronic device module may further include a heat diffusion portion protruding from the one surface of the heat transfer portion, and disposed along a circumference of the heat release portion.

The signal transmission portion may include: a connection conductor having one end connected to the substrate, and another end connected externally through a connection terminal; and an insulating portion embedding the connection conductor in the insulating portion.

The signal transmission portion may be formed by at least one solder ball embedded in the sealing portion.

In another general aspect, a method of manufacturing an electronic device module includes: mounting a signal transmission portion and a heating element on a first surface of a substrate; coupling a heat radiating portion to one surface of the heating element; forming a sealing portion sealing the signal transmission portion, the heating element, and the heat radiating portion; and partially removing the sealing portion to expose a portion of the heat radiating portion externally of the sealing portion. An exposed surface of the heat radiating portion is coplanar with an external surface of the sealing portion.

The partially removing of the sealing portion may include partially removing the sealing portion by grinding the sealing portion.

The heat radiating portion may include a heat transfer portion having an area larger than an area of the heating element, and a heat release portion protruding from one surface of the heat transfer portion. The heat release portion may have an area smaller than the area of the heat transfer portion, and may form the exposed surface of the heat radiating portion.

Other features and aspects will be apparent from the following detailed description, the drawings, and the claims.

### BRIEF DESCRIPTION OF DRAWINGS

FIG. 1 is a cross-sectional view schematically illustrating an electronic device module, according to an embodiment.

FIG. 2 is a plan view of the electronic device module shown in FIG. 1.

FIG. 3 is a cross-sectional view illustrating a state in which the electronic device module shown in FIG. 1 is mounted on a main substrate.

FIGS. 4A to 4C are cross-sectional views illustrating a method of manufacturing the electronic device module shown in FIG. 1.

FIGS. 5 to 8 are cross-sectional views illustrating a heat radiating portion, according to an embodiment.

FIG. 9 is a cross-sectional view schematically illustrating an electronic device module, according to an embodiment.

FIG. 10 is a cross-sectional view schematically illustrating an electronic device module, according to an embodiment.

FIG. 11 is a plan view of the electronic device module shown in FIG. 10.

FIG. 12 is a cross-sectional view illustrating a state in which the electronic device module illustrated in FIG. 10 is mounted on a main substrate.

FIGS. 13A to 13C are views illustrating examples in which a heating element is mounted in the electronic device module illustrated in FIG. 1.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as illustrated in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes illustrated in the drawings may occur. Thus, the examples described herein are not limited to the specific shapes illustrated in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

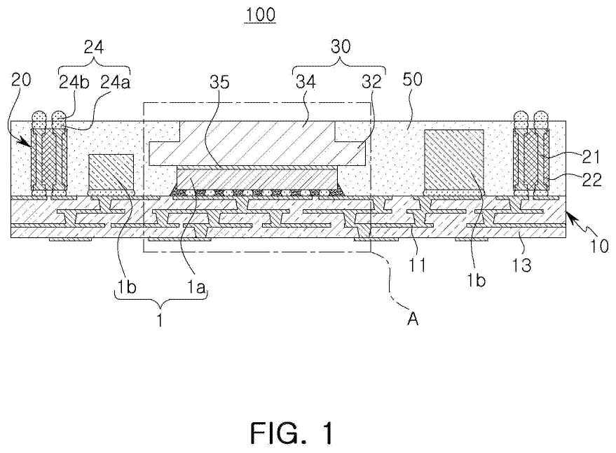

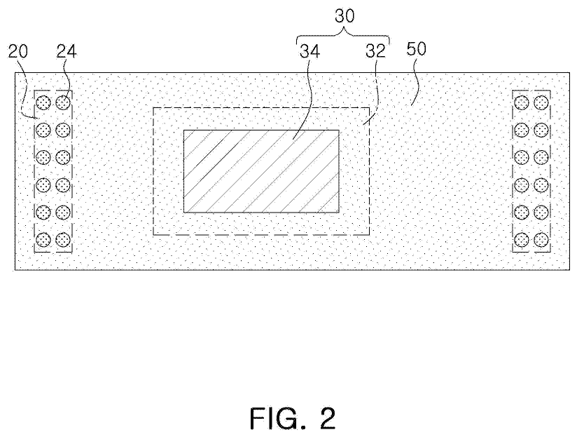

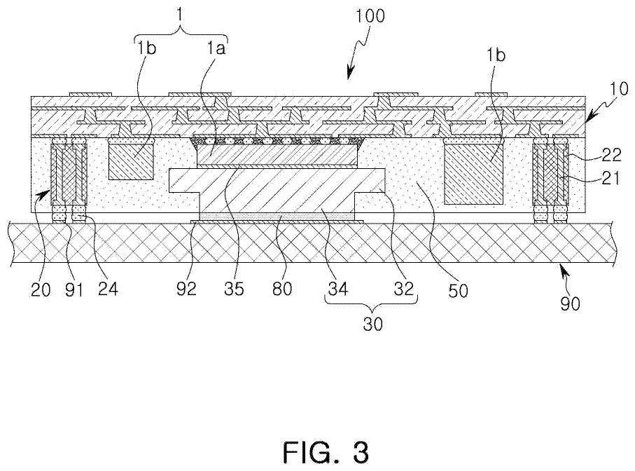

FIG. 1 is a cross-sectional view schematically illustrating an electronic device module 100, according to an embodiment. FIG. 2 is a plan view of the electronic device module 100. In addition, FIG. 3 is a cross-sectional view illustrating a state in which the electronic device module 100 is mounted on a main substrate 90.

Referring to FIGS. 1 to 3, the electronic device module 100 may be, for example, an electronic device module configured to transmit and receive wireless signals using a millimeter wave band. The electronic device module 100 may include, for example, a substrate 10, an element portion 1, a signal transmission portion 20, a sealing portion 50, and a heat radiating portion 30.

The substrate 10 may be, for example, a multilayer substrate 10 formed by repeatedly stacking a plurality of insulating layers 13 and a plurality of wiring layers 11. However, if necessary, it is also possible to use a double-sided substrate in which a wiring layer 11 is formed on opposing surfaces of one insulating layer. For example, various types of substrates (e.g., a printed circuit board, a flexible substrate, a ceramic substrate, a glass substrate, and the like) may be used as the substrate 10.

The wiring layer electrically connects the elements provided in the element portion 1. A metal having conductivity, such as copper (Cu), nickel (Ni), aluminum (Al), silver (Ag), or gold (Au), may be used as the wiring layer 11.

The element portion 1 includes at least one electronic device. The at least one electronic device may be mounted on either one or both of first and second surfaces of the substrate 10. The first and second surfaces may be upper and lower surfaces, respectively, when the electronic device module 100 is mounted on the main substrate 90 (FIG. 3). The at least one electronic device may, for example, include one or more active devices and/or one or more passive devices.

In addition, the element portion 1 may include a general element 1b and a heating element 1a that generates a substantial amount of heat during an operation. The heating element 1a may include an active surface on which a terminal is formed and an inactive surface, opposite to the active surface, and may be mounted on the second surface of the substrate 10.

A signal transmission portion 20 may be disposed on the second surface of the substrate 10 along with the element portion 1, and may have a higher mounting height than the element portion 1. Therefore, the signal transmission portion 20 may protrude farther from the second surface of the substrate 10 than the element portion 1.

In addition, the signal transmission portion 20 may include a connection conductor 21, one end of which is electrically connected to the substrate 10, and an insulating portion 22 disposed around the connection conductor 21 to protect the connection conductor 21.

The connection conductor 21 is disposed in the sealing portion 50 and passes through the sealing portion 50. A first end of connection conductor 21 is bonded to the substrate 10 and a second end of the connection conductor 21 is connected to a connection terminal 24. Therefore, the connection conductor 21 may be configured in various forms as long as it can be electrically connected between the substrate 10 and the connection terminal 24.

The connection conductor 21 may be formed of a conductive material, for example, copper, gold, silver, aluminum, or an alloy of copper, gold, silver, or aluminum.

The insulating portion 22 is disposed on a surface of the connection conductor 21 to protect the connection conductor 21. Therefore, the insulating portion 22 embeds the connection conductor 21 therein and exposes only first and second end portions of the connection conductor 21 externally. The insulating portion 22 may be formed of an insulating resin material. However, the insulating portion is not limited to a resin material.

The signal transmission portion 20 configured as described above may be, for example, a printed circuit board (PCB). In this case, conductive vias may be used as the connection conductor 21. However, the configurations of the signal transmission portion 20 and the connection conductor 21 are not limited to the described examples, and various modifications are possible, as necessary.

In the embodiment of FIG. 1, since the signal transmission portion 20 is embedded in the sealing portion 50, the sealing portion 50 may perform a function of the insulating portion 22. Therefore, if necessary, it is also possible to omit the insulating portion 22 and configure the signal transmission portion 20 to include only the connection conductor 21.

A connection terminal 24 may be coupled to the second end of the connection conductor 21.

The connection terminal 24 physically and electrically connects the electronic device module 100 and the main substrate 90 (FIG. 3) to each other, when the electronic device module 100 is mounted on the main substrate 90.

The connection terminal 24 may include a first connection terminal 24a and a second connection terminal 24b.

The first connection terminal 24a is bonded to the connection conductor 21 and is disposed in the sealing portion 50. The second connection terminal 24b is disposed externally of the sealing portion 50 and is bonded to the first connection terminal 24a. In addition, the second connection terminal 24b may be bonded to the main substrate 90, which is an external component, to electrically connect the first connection terminal 24a to the main substrate 90.

The connection terminal 24 may be formed of a conductive material and may be in the form of a solder bump or a solder ball, for example.

As shown in FIG. 2, the signal transmission portion 20 may be formed in a bar form (based on a lower surface in FIG. 1) and two signal transmission portions 20 may be spaced apart and disposed side by side (e.g., at opposite side of the substrate 10). However, the disclosure is not limited to this example, and various modifications are possible, as necessary, such as forming a signal transmission portion 20 in a rectangular ring shape along a contour of the substrate 10, or forming the signal transmission portion 20 in a curved linear shape, a circular shape, an elliptical shape, an irregular shape, or the like.

The heat radiating portion 30 is coupled to the inactive surface of the heating element 1a to discharge heat generated from the heating element 1a externally. To this end, the heat radiating portion 30 includes a heat transfer portion 32 and a heat release portion 34. The heat transfer portion 32 and the heat release portion 34 are formed as a single structure and have a difference only in their respective horizontal areas.

The heat transfer portion 32 may be formed in a flat plate shape or a block shape, and a first surface of heat transfer portion 32 is bonded to the inactive surface of the heating element 1a. In addition, at least one heat release portion 34 may be disposed on a second surface of the heat transfer portion 32.

Accordingly, heat that is conducted from the heating element 1a to the heat transfer portion 32 may be discharged externally through the heat release portion 34.

The heat transfer portion 32 may be bonded to one surface of the heating element 1a through the bonding layer 35. The bonding layer 35 may be formed by applying a resin-based adhesive solution such as epoxy to the inactive surface of the heating element 1a or the first surface of the heat transfer portion 32. The bonding layer 35 may be formed of a non-conductive material, but is not limited thereto. For example, it is also possible to form a metal thin film layer by a method such as soldering, or the like, and use the metal thin film layer as the bonding layer 35.

In the illustrated example, the heat transfer portion 32 is formed in a square flat plate shape, and is formed to have a horizontal area larger than the horizontal area of the inactive surface of the heating element 1a. However, the shape of the heat transfer portion 32 is not limited to the example described herein, and various modifications are possible.

The heat release portion 34 is disposed in a form protruding from the second surface of the heat transfer portion 32, and at least a portion of the heat release portion 34 is exposed externally of the sealing portion 50.

The heat radiating portion 34 has a horizontal area smaller than the horizontal area of the heat transfer portion 32. More specifically, the heat radiating portion 30 may have a form in which the horizontal area becomes smaller from the heat transfer portion 32 toward the heat release portion 34.

In the present embodiment, due to the difference in size between the heat transfer portion 32 and the heat release portion 34, a step in a form of one or more stairs may be formed on the side surface of the heat radiating portion 30. However, the side shape of the heat radiating portion 30 is not limited to the described example.

An exposed surface of the heat release portion 34 exposed externally of the sealing portion 50 may be disposed on the same plane as the surface of the sealing portion 50 on which the exposed surface is disposed of the heat release portion 34. Therefore, the exposed surface of the heat release portion 34 may be formed as a flat surface.

The heat release portion 34 may have the same thickness as the heat transfer portion 32. However, the disclosure herein is not limited to such a configuration, and the heat release portion 34 may be formed to have a thickness different from a thickness of the heat transfer portion 32.

The heat radiating portion 30 may be formed of various materials as long as it is formed of a high thermal conductivity material. For example, the heat radiating portion 30 may be formed of a metal material, and may be made of a material such as Cu, Ni, Ti, Au, or Sn. However, the heat radiation portion 30 is not limited to the described materials, and a non-metal material having high thermal conductivity such as graphite may be used for the heat radiation portion 30.

The sealing portion 50 is formed on the second surface of the substrate 10. Therefore, the sealing portion 50 may embed the element portion 1 and the signal transmission portion 20, which are mounted on the second surface of the substrate 10.

The sealing portion 50 is filled between the respective elements 1a and 1b constituting the element portion 1, thereby preventing electrical shorts from occurring between the elements 1a and 1b, and surrounds the outside of the elements 1a and 1b and fixes the elements 1a and 1b on the substrate 10 to safely protect the elements 1a and 1b from external impacts.

In addition, the sealing portion 50 may embed the signal transmission portion 20 to securely fix the signal transmission portion 20 to the substrate 10 and protect it from external impacts. Since the sealing portion 50 is provided, as shown in FIG. 2, only the connection terminals 24 and the heat release portion 34 are exposed externally of the sealing portion 50 on the lower surface of the electronic device module 100.

The sealing portion 50 is formed of an insulating material. For example, an epoxy molding compound (EMC) may be used to form the sealing portion 50. However, the sealing portion 50 is not limited to an EMC.

Referring to FIG. 3, the main substrate 90, on which the electronic device module 100 is mounted, may be a circuit board provided in an electronic device (for example, a mobile terminal, a computer, a laptop, a TV, or the like). Therefore, various known substrates such as a printed circuit board, a flexible substrate, a ceramic substrate, a glass substrate, and the like, may be used as the main substrate 90.

Still referring to FIG. 3, a plurality of electrode pads may be provided on a first surface of the main substrate 90. The plurality of electrode pads may include a signal pad 91 connected to the connection terminal 24 and a heat dissipation pad 92 connected to the heat release portion 34.

The electronic device module 100 may be disposed on the main substrate 90 by disposing the lower surface of the electronic device module 100, and thus the exposed surface of the heat radiating portion 30, in a form facing the main substrate 90.

In order to increase the thermal conductivity between the electronic device module 100 and the main substrate 90, a heat transfer layer 80 may be disposed between the main substrate 90 and the heat radiating portion 30. The heat transfer layer 80 may be disposed such that one surface of the heat transfer layer 80 contacts the upper surface of the main substrate 90 and the other surface of the heat transfer layer 80 contacts the lower surface of the heat radiating portion 30.

The heat transfer layer 80 may be formed of a thermal interface material (TIM).A liquid type such as paste or grease, a sheet type, or a pad type formed of silicon, or the like may be selectively used as the TIM. However, the heat transfer layer 80 is not limited to the described example materials, and various materials, such as a conductive adhesive, may be used as long as the material has a high thermal conductivity. For example, the heat transfer layer 80 may be formed of a conductive adhesive containing silver (Ag) or an epoxy resin-based resin adhesive.

A method of manufacturing the electronic device module 100, according to an embodiment, is described below.

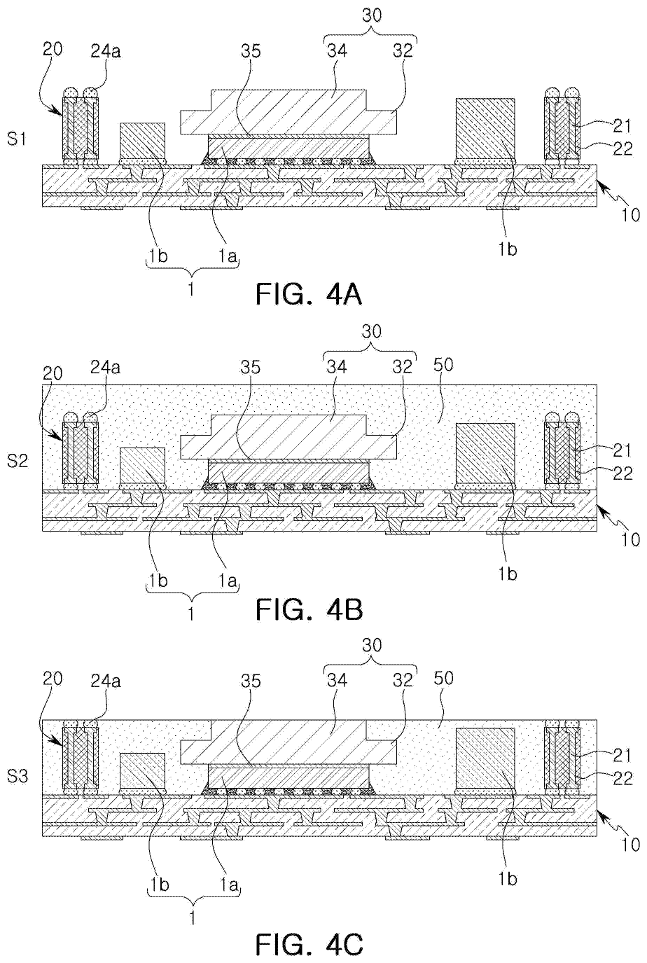

FIGS. 4A to 4C are views illustrating a method of manufacturing the electronic device module 100, according to an embodiment.

Referring to FIG. 4A, in the method of manufacturing the electronic device module 100, first, in operation 51, the element portion 1 and the signal transmission portion 20 are formed on the second surface of the substrate 10. The element portion 1 and the signal transmission portion 20 may be collectively mounted on the substrate 10 through a conductive adhesive such as solder.

Subsequently, in operation 51, the heat radiating portion 30 is disposed on the inactive surface of the heating element 1a. Then, the first connection terminal 24a is attached to the second end of the connection conductor 21.

As described above, the heat radiating portion 30 may be bonded to the heating element 1a through the bonding layer 35.

In the described embodiment, a case in which the heating element 1a is first mounted on the substrate 10, and then the heat radiating portion 30 is bonded to the heating element 1a is provided as an example. However, it is also possible that the heat radiating portion 30 is first bonded to the heating element 1a, and then the heating element 1a to which the heat radiating portion 30 is bonded to the substrate 10.

Referring to FIG. 4B, subsequently, the sealing portion 50 is formed to embed the entire element portion 1 and the signal transmission portion 20 in operation S2. The sealing portion 50 may be formed by transfer molding an epoxy molding compound (EMC), but is not limited to an EMC.

In the process of forming the sealing portion 50, the entire heat radiating portion 30 and the first connection terminal 24a may also be completely embedded in the sealing portion 50.

Referring to FIG. 4C, subsequently, a portion of the sealing portion 50 is removed in operation S3, so that the first connection terminal 24a and the heat radiating portion 30 are exposed S3. The sealing portion 50 may be removed by a grinding method using a grinder. Accordingly, the sealing portion 50 may be removed such that the thickness of the sealing portion 50 is reduced.

Since the sealing portion 50 is partially removed, the heat radiating portion 30 and the first connection terminal 24a are partially exposed on one surface of the sealing portion 50. In addition, the exposed surface of the heat radiating portion 30 and the exposed surface of the first connection terminal 24a are disposed on the same plane as the surface of the sealing portion 50 on which a grinding process is performed.

Subsequently, in operation S3, the second connection terminal 24b is formed on the exposed surface of the first connection terminal 24a to complete the electronic device module 100. In this case, the bonding surfaces of the first connection terminal 24a and the second connection terminal 24b are disposed on the same plane as the exposed surface of the heat radiating portion 30 and the surface of the sealing portion 50.

The electronic device module 100 configured as above may dissipate heat of the heating element 1a toward the main substrate 90 through the heat transfer portion 32 and the heat release portion 34. Therefore, the heat dissipation characteristics of the electronic device module 100 may be improved compared to a conventional electronic device module.

In addition, since the heat radiating portion 30 is exposed externally of the sealing portion 50 by a grinding method, a manufacturing process can be simplified, thereby increasing mass productivity.

In addition, since a step is provided on the side surface of the heat radiating portion 30, a contact area between the heat radiating portion 30 and the sealing portion 50 may be extended, thereby increasing the bonding reliability between the heat radiating portion 30 and the sealing portion 50.

Further, even if the interface between the heat release portion 34 and the sealing portion 50 peels or cracks are generated in a vicinity of the interface, peeling or cracks may be prevented from expanding to surrounding areas due to the step difference between the heat transfer portion 32 and the heat release portion 34.

As described above, in the electronic device module 100, the heat radiating portion 30 initially completely embeds the heat radiating portion 30 in the sealing portion 50, and then a surface of the heat radiating portion 30 is exposed externally of the sealing portion 50 through a grinding method. Therefore, the height of the electronic device module 100 may be uniformly manufactured regardless of a mounting state of the heat radiating portion 30.

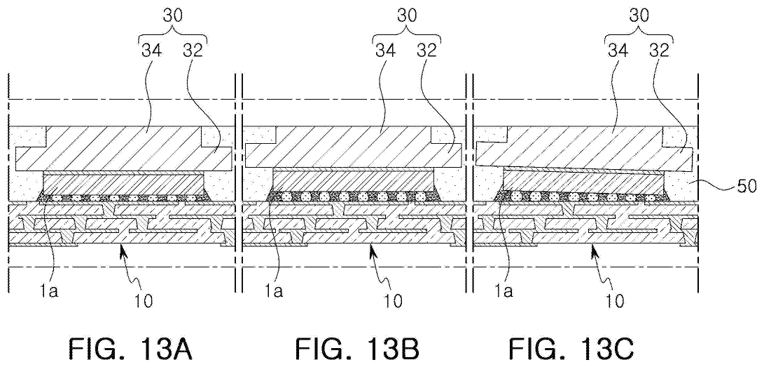

FIGS. 13A to 13C are cross-sectional views illustrating various mounting states of the heating element 1a and the heat radiating portion 30, according to embodiments.

FIG. 13A illustrates a state in which the heating element 1a is normally mounted, and FIG. 13B illustrates a state in which the heating element 1a is mounted such that a space between the heating element 1a and the substrate 10 is relatively large. In this case, the heat release portion 34 of the heat radiating portion 30 may be reduced in thickness compared to FIG. 13A.

In addition, FIG. 13C illustrates a case in which the heating element 1a is mounted on the substrate 10 in an inclined state. In this case, the heat release portion 34 of the heat radiating portion 30 may be disposed in an inclined state, and a thickness of one side (a left side in the drawing) of the heat release portion 34 and a thickness of another side (a right side in the drawing) of the heat release portion 34 may be different.

As described above, in the manufacturing method according to an embodiment, even when the heating element 1a is mounted in a state somewhat spaced apart from the substrate 10 or mounted in a state to be inclined, the exposed surface of the heat radiating portion 30 is always disposed on the same plane as the surface of the sealing portion 50 and the thickness of the electronic device module 100 is kept constant. Therefore, a problem such as protruding of the heat radiating portion 30 externally of the sealing portion 50 can be prevented.

In the above-described embodiment, a case in which the heat transfer portion 32 and the heat release portion 34 are configured as one structure is described. In this case, the heat radiating portion 30 may be provided through cutting processing, press processing, stamping processing, and the like. However, the disclosure is not limited to this example, and various modifications are possible, such as preparing and providing the heat transfer portion 32 and the heat release portion 34 separately, and then bonding the heat transfer portion 32 and the heat release portion 34 to each other to complete the heat radiating portion 30.

In addition, the heat radiating portion 30 is not limited to the above-described embodiment, and various modifications are possible.

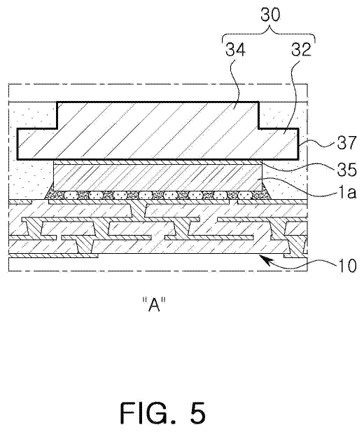

FIGS. 5 to 8 are partial cross-sectional views of electronic device modules, according to embodiments, and are enlarged and illustrated in part A of FIG. 1.

Referring to FIG. 5, a coupling layer 37 having an increased surface roughness may be formed on a surface of the heat radiating portion 30.

The coupling layer 37 may be formed by performing surface treatment the heat radiating portion 30 formed of a metal material. For example, the coupling layer 37 may be formed of a black oxide film formed through an alkali treatment.

Since the heat radiating portion 30 is formed of a metal material, there is a large difference between a coefficient of thermal expansion (CTE) of the heat radiating portion 30 and a CTE of the sealing portion 50, which is formed of a resin material. Therefore, peeling may occur at the interface between the sealing portion 50 and the heat radiating portion 30 by heat generated while the electronic device module is operating.

However, when the coupling layer 37 with increased roughness is formed on the surface of the heat radiating portion 30 as illustrated in FIG. 5, the coupling layer 37 is combined with the sealing portion 50. Due to the coupling layer 37 having increased roughness, a surface area of the coupling layer 37 may be increased by 200% compared to a surface area of the heat radiating portion 30 without the coupling layer 37. Therefore, the bonding area with the sealing portion 50 can be greatly expanded, and since the roughness is large, the mechanical coupling force with the sealing portion 50 is also increased.

Accordingly, since the coupling force between the sealing portion 50 and the heat radiating portion 30 can be increased, peeling at the interface between the sealing portion 50 and the heat radiating portion 30 may be minimized.

The coupling layer 37 may also be applied to the heat radiating portion disclosed in other embodiments herein.

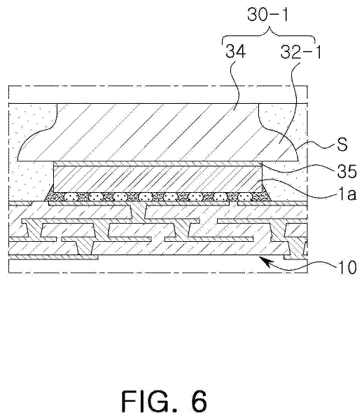

Referring to FIG. 6, at least a portion of the side surfaces S of a heat radiating portion 30-1 is formed as a curved surface. The heat radiating portion 30-1 has an increased horizontal area toward the bonding surface with the heating element 1a, and due to the increase in area, the side surface S of the heat radiating portion 30 is formed as a curved surface. For example, a heat transfer portion 32-1 of the heat radiating portion 30-1 may have an increased horizontal area and may include a portion of the side surface S that is formed as the curved surface.

Such a configuration may be provided by manufacturing the heat radiating portion 30-1 through a chemical process, for example, an etching method. In this case, a plurality of heat radiating portions 30-1 can be manufactured collectively. However, the heat radiating portion 30-1 is not limited to being formed by an etching method, and may also be formed through the above-described physical process such as stamping processing.

As described above, the shape of the heat radiating portion 30-1 may be modified in various ways.

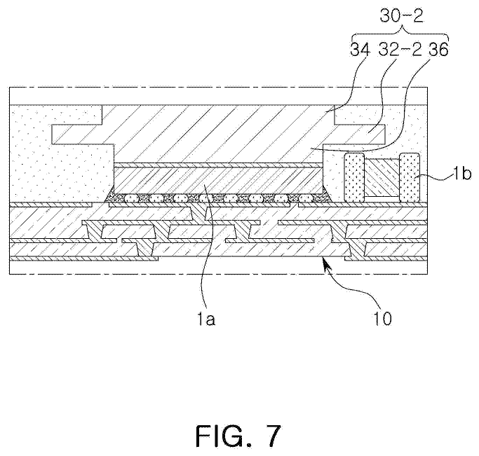

Referring to FIG. 7, a heat radiating portion 30-2 includes a protrusion 36 formed to protrude from a heat transfer portion 32-2 toward the heat generating element 1a.

The protrusion 36 is formed to protrude from the other surface of the heat transfer portion 32 and have a horizontal area smaller than a horizontal area of the heat transfer portion 32, and is bonded to the heating element 1a. Since the protrusion 36 is formed, a step due to a difference in area between the protrusion 36 and the heat transfer portion 32-2 may be formed in a portion in which the protrusion 36 and the heat transfer portion 32-2 are connected.

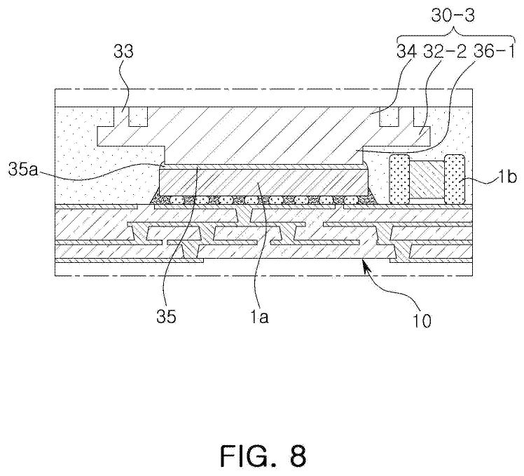

The protrusion 36 may protrude from an area corresponding to an area of the inactive surface area of the heating element 1a. However, the disclosure is not limited to this configuration. For example, as shown in a heat radiating portion 30-3 FIG. 8, it is also possible to configure a protrusion 36-1 to protrude to have an area smaller than the area of the inactive surface of the heating element 1a.

Referring to FIGS. 7 and 8, since the heat radiating portions 30-2 and 30-3 have respective protrusions 36 and 36-1, the distance between the substrate 10 and the heat transfer portion 32-2 may be increased in the electronic device module compared to the previously described embodiments. Accordingly, at least one general element 1b may be disposed between the substrate 10 and the heat transfer portion 32-2.

For example, the general element 1b may be disposed such that at least a portion thereof faces the lower surface of the heat transfer portion 32-2. In this case, a degree of integration of the element portion 1 mounted on the substrate 10 can be increased.

A distance over which the protrusions 36 and 36-1 protrude is not particularly limited. For example, the thickness of the protrusions 36 and 36-1 (that is, a protruding distance) and the thickness of the heat discharge portion 34 may be configured to be the same. In addition, when the general element 1b is disposed in a lower portion of the heat transfer portion 32-2, the thickness of the protrusions 36 and 36-1 may be increased to prevent contact between the heat transfer portion 32-2 and the general element 1b.

As illustrated in FIG. 8, when the protrusion 36-1 protrudes having a smaller area than the area of the inactive surface of the heating element 1a, a step may be formed between the protrusion 36-1 and the heating element 1a.

In FIG. 8, at least a portion of the bonding layer 35 may be disposed in the step space. The bonding layer 35 may be formed by applying a bonding solution between the heat radiating portion 30-3 and the heating element 1a when the heat radiating portion 30-3 is bonded to the heating element 1a. In this process, a surplus solution 35a in the bonding solution may be cured by being collected in the above-described step space. In this case, at least a portion of the surplus solution 35a may contact the side surface of the protrusion 36.

In the absence of the above-described step difference, there is no space in which the above-described surplus solution can be collected, so the surplus solution can flow to the substrate 10 along the side surface of the heating element 1a. However, the electronic device module of FIG. 8 can prevent unnecessary diffusion of the surplus solution 35a to the substrate 10, or the like, by providing the above-described step.

Still referring to FIG. 8, the heat radiating portion 30-3 may further include a heat diffusion portion 33 protruding from the heat transfer portion 32.

The heat diffusion portion 33 may protrude from a region in which where the heat radiating portion 34 is not disposed on one surface of the heat transfer portion 32-2, and the end of the heat diffusion portion 33 may be exposed externally of the sealing portion 50. However, the heat diffusion portion 33 may be configured to be disposed in the sealing portion 50.

The heat diffusion portion 33 may be continuously disposed along a periphery of the heat radiating portion 34. However, the heat diffusion portion 33 is not limited to such a configuration, and it is also possible to dispose the heat radiating portion 34 to include a plurality of pieces in a broken line.

When the heat diffusion portion 33 is provided as described above, since the bonding area between the heat radiating portion 30-3 and the sealing portion 50 can be increased, bonding reliability can be increased. In addition, the thermal stress generated at an interface between the heat radiating portion 30-3 and the sealing portion 50 due to a difference in thermal expansion coefficient between the heat radiating portion 30 and the sealing portion 50 may be distributed as much as possible.

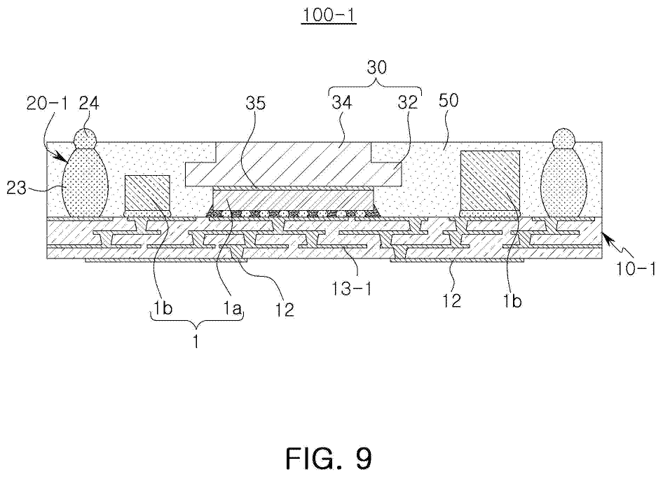

Referring to FIG. 9, an electronic device module 100-1, according to an embodiment, may include an antenna 12.

Specifically, a wiring layer 11-1 of the substrate 10-1 may include at least one antenna 12. The antenna 12 may be disposed on at least one of a first surface or a side surface of the substrate 10-1, and an inside of the substrate 10-1. However, the disclosure is not limited to such a configuration, and a chip antenna element may be separately provided and mounted on the first surface of the substrate 10-1.

The antenna 12 may include any one or any combination of any two or more of a dipole antenna, a monopole antenna, and a patch antenna, but is not limited to these examples.

The antenna 12 may basically be understood to be a radiator, and may also be understood as a structure including a wiring connecting the radiator and an electronic device. In addition, the antenna 12 may emit or receive RF signals in the millimeter wave band.

The antenna 12 and the heating element 1a may be respectively disposed on the first and second surfaces of the substrate 10-1. For example, as shown in FIG. 9, when the antenna 12 is disposed on the first surface of the substrate 10-1, the heating element 1a may be mounted on the second surface of the substrate 10-1 in a flip chip bonding structure.

Since the element portion 1 and the antenna 12 are spaced apart by the thickness of the substrate 10-1, a spacing distance may be minimized. Accordingly, signal power loss may be minimized and deterioration of reflection characteristics may be reduced.

In addition, the electronic device module 100-1 configures a signal transmission portion 20-1 using a conductive member 23. For example, at least one solder ball may be embedded in the sealing portion and used as the signal transmission portion 20-1.

In this example, the signal transmission portion 20-1 may not be formed as a single member and may be configured in a form in which a plurality of conductive members 23-1 are disposed to be spaced apart.

In a manufacturing method of the electronic device module 100-1, the conductive members 23, which are separately manufactured, may be mounted on the second surface of the substrate 10-1, and then the sealing portion 50 for embedding the conductive members 23 may be formed. In this example, since the conductive members 23 are disposed to be spaced apart, a flow of a molding resin, which is a raw material of the sealing portion 50, is facilitated through the space between the conductive members 23. Therefore, the electronic device module 100-1 is easy to manufacture.

Subsequent manufacturing processes may be performed similarly to the above-described embodiments.

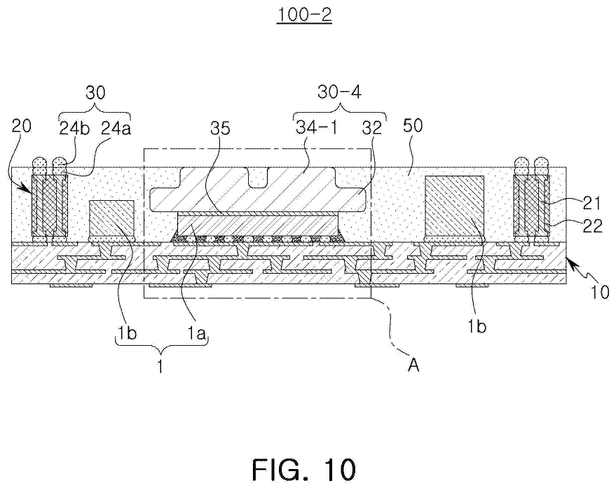

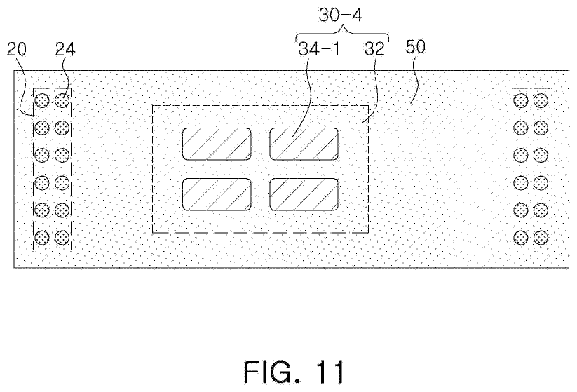

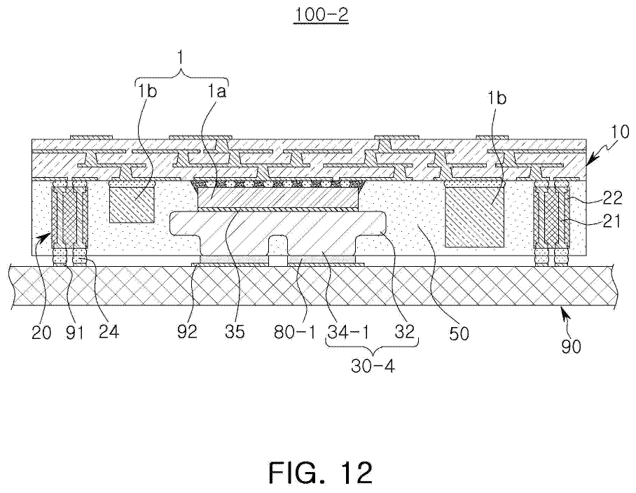

FIG. 10 is a cross-sectional view schematically illustrating an electronic device module 100-2, according an embodiment. FIG. 11 is a plan view of the electronic device module 100-2. FIG. 12 is a cross-sectional view illustrating a state in which the electronic device module 100-2 is mounted on the main substrate 90.

Referring to FIGS. 10 to 12, a heat radiating portion 30-4 of the present embodiment includes a plurality of heat release portions 34-1.

The heat release portions 34-1 are configured such that four heat release portions 34-1 are spaced apart from one another. Accordingly, the heat radiating portion 30-4 is provided with a plurality of exposed surfaces having a relatively small area, rather than a single exposed surface having a large area.

All four heat radiating portions 34-1 may be formed to have the same size, and all areas of the exposed surface exposed externally of the sealing portion 50 may be formed to be the same. However, the present disclosure is not limited to this configuration, and it is also possible to configure the volume or the area of the exposed surface differently.

As described above, when the heat radiating portion 30-4 has a plurality of exposed surfaces, it is possible to suppress exposure of the exposed surface externally of a heat transfer layer 80-1 shown in FIG. 12.

When the heat transfer layer 80-1 is formed with a conductive adhesive, the heat transfer layer 80-1 may be cured after being disposed between the exposed surface of the heat radiating portion 30-4 and the electrode pad 92 of the main substrate 90 in a paste state. In this process, the conductive adhesive in the paste state is cured and the volume of the conductive adhesive is reduced.

For example, when the area of the exposed surface of a heat radiating portion exceeds 1 mm², the paste-state heat transfer layer disposed between the exposed surface of the heat radiating portion and the electrode pad 92 of the main substrate 90 may be cured, and the volume of the paste-state heat transfer layer disposed between the exposed surface of the heat radiating portion and the electrode pad may be excessively reduced, so that the exposed surface of the heat radiating portion or the electrode pad 92 of the main substrate 90 may be exposed externally of the heat transfer layer. In this case, heat transfer efficiency between the electronic device module and the main substrate 90 may be reduced.

Therefore, in the embodiment disclosed herein, in order to solve the above-described problem, the heat radiating portion 30-4 of the electronic device module 100-2 is configured to include a plurality of exposed surfaces having a small area and disposed to be spaced apart from each other, rather than one exposed surface having a large area.

Thus, the heat transfer layer 80-1 is separated into a plurality of sections, and is bonded to the above-described plurality of exposed surfaces, respectively. As such, when the heat transfer layer 80-1 is separated into a plurality of sections, a change in sizes that is reduced in the curing process is distributed to the respective heat transfer layers 80-1.

Therefore, it is possible to prevent the exposed surface of the heat radiating portion 30-4 or the electrode pad 92 of the main substrate 90 from being exposed externally of the heat transfer layer 80-1. Accordingly, it is possible to increase the heat transfer efficiency.

In FIGS. 10-12, an example including four separate heat release portions 34-1 is provided as an example. However, various modifications are possible, such as forming a groove partitioning a heat release portion (e.g., the heat release portion 34 of FIGS. 1 to 3) into multiple portions so that only the exposed portion of the heat release portion is divided.

In addition, the respective heat release portions disclosed in the various embodiments herein are not limited to a quadrangular shape, and may be modified in various forms as necessary, such as a circular or elliptical shape.

As set forth above, according to the disclosure herein, since heat generated by a heating element can be discharged to a main substrate through a heat radiating portion, it is possible to improve heat dissipation characteristics of an electronic device module compared to the prior art.

Modifications and variations of the above embodiments are within the scope of this disclosure. For example, when the heating element is electrically connected to the substrate through a bonding wire, the heat transfer portion may be bonded to the active surface of the heating element.

In addition, the above-described embodiments may be configured in combination with each other. For example, the conductive member 23 illustrated in FIG. 9 may be applied to the electronic device modules disclosed in other embodiments.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. In addition, respective embodiments may be combined with each other. For example, the pressing members disclosed in the above-described embodiments may be used in combination with each other in one force sensing device. Therefore, the scope of the disclosure is defined not by the detailed description, but by the claims and their equivalents, and all variations within the scope of the claims and their equivalents are to be construed as being included in the disclosure.

What is claimed is:

1. An electronic device module, comprising:
a substrate;
a heating element mounted on a first surface of the substrate;
a heat radiating portion coupled to one surface of the heating element;
a signal transmission portion mounted on the first surface of the substrate and configured to electrically connect the substrate externally; and
a sealing portion sealing the heating element, the heat radiating portion, and the signal transmission portion,
wherein the heat radiating portion comprises:
a heat transfer portion having an area larger than an area of the heating element; and
a heat release portion protruding from one surface of the heat transfer portion, the heat release portion having an area smaller than the area of the heat transfer portion and having an exposed surface coplanar with an external surface of the sealing portion.

2. The electronic device module of claim 1, wherein the heat transfer portion is formed in a flat plate shape or a block shape, and is formed of a metal material.

3. The electronic device module of claim 1, further comprising:
connection terminals configured to electrically connect the signal transmission portion externally,
wherein the connection terminals each comprise a first connection terminal disposed in the sealing portion and bonded to the signal transmission portion, and a second connection terminal disposed externally of the sealing portion and bonded to the first connection terminal.

4. The electronic device module of claim 3, wherein a bonding surface of the first connection terminal and the second connection terminal is coplanar with the exposed surface of the heat release portion.

5. The electronic device module of claim 1, wherein the exposed surface of the heat release portion comprises a plurality of exposed surfaces disposed to be spaced apart.

6. The electronic device module of claim 1, wherein a coupling layer having an increased surface roughness in comparison to the heat radiating portion is formed on a surface of the heat radiating portion.

7. The electronic device module of claim 1, wherein a step is formed on a side surface of the heat radiating portion.

8. The electronic device module of claim 1, wherein a side surface of the heat radiation portion is formed as a curved surface.

9. The electronic device module of claim 1, wherein the heat radiating portion further comprises a protrusion protruding from another surface of the heat transfer portion and bonded to the heating element, and
wherein the protrusion has an area smaller than the area of the heat transfer portion.

10. The electronic device module of claim 9, wherein a bonding surface of the protrusion that is bonded to the heating element has an area smaller than an area of the one surface of the heating element.

11. The electronic device module of claim 10, further comprising:
a bonding layer interposed between the heating element and the protrusion,
wherein at least a portion of the bonding layer is disposed in a stepped space formed by a difference in area between the protrusion and the one surface of the heating element.

12. The electronic device module of claim 9, further comprising:
an element mounted on the first surface of the substrate,
wherein at least a portion of the element is disposed to face a lower surface of the heat transfer portion.

13. The electronic device module of claim 1, further comprising a heat diffusion portion protruding from the one surface of the heat transfer portion, and disposed along a circumference of the heat release portion.

14. The electronic device module of claim 1, wherein the signal transmission portion comprises a connection conductor having one end connected to the substrate, and another end connected externally through a connection terminal; and
an insulating portion embedding the connection conductor in the insulating portion.

15. The electronic device module of claim 1, wherein the signal transmission portion is formed by at least one solder ball embedded in the sealing portion.

16. A method of manufacturing an electronic device module, comprising:
mounting a signal transmission portion and a heating element on a first surface of a substrate;
coupling a heat radiating portion to one surface of the heating element;
forming a sealing portion sealing the signal transmission portion, the heating element, and the heat radiating portion; and
partially removing the sealing portion to expose a portion of the heat radiating portion externally of the sealing portion,
wherein an exposed surface of the heat radiating portion is coplanar with an external surface of the sealing portion.

17. The method of claim 16, wherein the partially removing of the sealing portion comprises partially removing the sealing portion by grinding the sealing portion.

18. The method of claim 16, wherein the heat radiating portion comprises a heat transfer portion having an area larger than an area of the heating element, and a heat release portion protruding from one surface of the heat transfer portion, and
wherein the heat release portion has an area smaller than the area of the heat transfer portion, and forms the exposed surface of the heat radiating portion.
